(19) United States
(12) Patent Application Publication
(10) Pub. No.: US 2013/0092216 A1
(43) Pub. Date: Apr. 18, 2013

(54) Solar Cell Module Junction Box

(71) Applicants: Weiping YAN, Suzhou (CN); Xiaogang ZHANG, Suzhou (CN); Zixia CHEN, Suzhou (CN); Zijian HUANG, Suzhou (CN); Biquan LIU, Suzhou (CN); Steven H. BIETZER, Sunnyvale, CA (US); David R. HARGIS, Sunnyvale, CA (US); Liya QIN, Suzhou (CN); Weifeng SHEN, Suzhou (CN); Jean-Nicolas JAUBERT, Suzhou (CN); Wenda ZHENG, Suzhou (CN); Guangyan LU, Suzhou (CN); Chao KUANG, Suzhou (CN)

(72) Inventors: Weiping YAN, Suzhou (CN); Xiaogang ZHANG, Suzhou (CN); Zixia CHEN, Suzhou (CN); Zijian HUANG, Suzhou (CN); Biquan LIU, Suzhou (CN); Steven H. BIETZER, Sunnyvale, CA (US); David R. HARGIS, Sunnyvale, CA (US); Liya QIN, Suzhou (CN); Weifeng SHEN, Suzhou (CN); Jean-Nicolas JAUBERT, Suzhou (CN); Wenda ZHENG, Suzhou (CN); Guangyan LU, Suzhou (CN); Chao KUANG, Suzhou (CN)

(73) Assignee: ARRAY POWER INC., Sunnyvale, CA (US)

(21) Appl. No.: 13/611,312

(22) Filed: Sep. 12, 2012

(30) Foreign Application Priority Data
Oct. 17, 2011 (CN) 201120394618.2
Oct. 17, 2011 (CN) 201120394619.7
Oct. 17, 2011 (CN) 201120394666.1

(51) Int. Cl. H01L 31/05; H05K 5/00; H01L 31/048

(52) U.S. Cl. 136/251; 361/752

(57) ABSTRACT

Systems, methods, and devices provide a solar cell module which may ensure a tight connection between a junction box and an external function module. The various embodiments provide a solar cell module having a junction box which may independently support an external function module and may firmly fix the external function module onto a base plate of the solar cell module. The various embodiments simplify the connecting structures between the external function box, the junction box, and the base plate of the solar cell module. The various embodiments provide a solar cell junction box which may enable a solar cell system to track the maximum power point of the solar cell modules in the solar cell system. In an embodiment, a junction box may include a printed circuit board (“PCB”).

### RELATED APPLICATIONS

This application claims priority under 35 U.S.C. §119 to People's Republic of China Patent Application 201120394619.7 entitled “A Junction Box and a Solar Cell Module and a Solar Cell System with the Junction Box” filed Oct. 17, 2011. This application also claims priority under 35 U.S.C. §119 to People's Republic of China Patent Application 201120394618.2 entitled “A Solar Cell Module” filed Oct. 17, 2011. This application also claims priority under 35 U.S.C. §119 to People's Republic of China Patent Application 201120394666.1 entitled “A Solar Cell Junction Box, and a Solar Cell Module and a Solar Cell System of Using Said Junction Box” filed Oct. 17, 2011. The entire contents of all three of these applications are incorporated herein by reference.

### FIELD OF THE INVENTION

The present invention relates generally to solar power generation systems, and more particularly to solar (i.e., photovoltaic) cell modules and junction boxes.

### BACKGROUND

Solar power may be viewed as a renewable and clean energy source when compared to conventional energy sources, such as burning fuel. A popular method for generating solar power is using a solar cell module to convert light to electricity. A solar module may include a plurality of solar cells connected together in arrays to form a unitary solar panel. In operation, a solar cell absorbs light and via the photovoltaic effect generates two different electric charges. The electromotive forces between the two different electric charges converts the light to electric current.

As a renewable energy source, solar power generated by solar cell systems is now widely used in power plants. A solar cell system may include a plurality of solar cell modules which may be connected in a series circuit. A solar cell system may include a plurality of solar cells as a core component. A solar cell system may further include a junction box, and an external function module connected to the solar cells. The external function module may be a device which may convert the voltage generated by the solar cells, such as inverter.

In a solar cell system, one covered (e.g., shaded) solar cell module in the series circuit may become a load and deplete the power being generated by other uncovered (e.g., un-shaded) solar cell modules. As a result, the covered solar cell module may begin to heat up, and this may lead to the “Hot Spot Effect” which may damage or destroy the solar cells. In a traditional solar cell system, a junction box connecting the solar cells to an external module may include a unitary insulated base, several terminals retained in the insulated base, several bypass diodes connecting with the terminals, and a cover over the insulated base. The bypass diodes of the junction box may be connected in parallel between the positive pole and negative pole of the solar cell module in order to prevent the “Hot Spot Effect”, and to avoid power depletion by the covered solar cells modules. In such a junction box, while the “Hot Spot Effect” may be avoided, the solar cell module will necessarily have a large power loss

In a traditional solar cell system, every solar cell panel may be connected together and then connected with a large inverter which may be used to track a maximum power point of all the connected solar cell panels. As the maximum power point is a value of all connected solar cell panels, rather than a value of each single solar cell panel, the inverter may not track every single solar cell panel's maximum power point. As a result, some single solar cell panels may not reach their own maximum power point. To address this problem, a plurality of smaller inverters may be used in the solar cell system. An independent smaller inverter may be placed on the back surface of each single solar cell panel, and the smaller inverter may be connected with a junction box of the solar cell panel. The smaller inverter may track a maximum power point for the single solar cell panel. In this manner, each single solar cell panel may be operated at its own maximum efficiency. The small inverter may also convert DC current generated from a solar cell panel to AC current, which may be necessary for external applications.

The Maximum Power Point Tracking (“MPPT”) of the solar cell system may be controlled by the large inverter. A typical junction box of a solar cell system may use diodes that are located inside the junction box, without capabilities for data storage and temperature testing. As a result, the external inverter may not receive data related to current/voltage (“IV”) curves from the junction box under Standard Test Conditions (“STC”).

A traditional connection between a junction box and an inverter is disclosed in Chinese Utility Model Patent Publication No.: CN201754410U. In Chinese Utility Model Patent Publication No.: CN201754410U the junction box is attached in the middle of a solar cell panel and includes a connector, and the inverter directly connects with the junction box. The junction box described in Chinese Utility Model Patent Publication No.: CN201754410U is mounted on a base plate of the panel by adhesive. In Chinese Utility Model Patent Publication No.: CN201754410U there is a locking member between the inverter and the junction box to engage with a locking portion of the junction box. Additionally, the inverter has several locking hooks on a bottom surface to engage with locking grooves of the base plate enabling a tight connection between the inverter and base plate.

However, the kind of inverter described in Chinese Utility Model Patent Publication No.: CN201754410U normally has a complicated mounting structure because a traditional junction box is not able to independently support the heavy load of the inverter. Thus, it is necessary to form locking structures not only between the junction box and the inverter, but also between the base plate and the inverter. Moreover, the base plate described in Chinese Utility Model Patent Publication No.: CN201754410U further defines several different shaped locking grooves, like L-shaped or T-shaped, which further complicates manufacturing processes and increases the cost of manufacturing.

### SUMMARY

The systems, methods, and devices of the various embodiments provide a solar cell module which may ensure a tight connection between a junction box and an external function module. The various embodiments provide a solar cell module having a junction box which may independently support an external function module and may firmly fix the external function module onto a base plate of the solar cell module. The various embodiments simplify the connecting structures between the external function box, the junction box, and the base plate of the solar cell module. The various embodiments provide a solar cell junction box which may enable a solar cell system to track the maximum power point of the solar cell modules in the solar cell system. In an embodiment, a junction box may include a printed circuit board (“PCB”).

### BRIEF DESCRIPTION OF THE DRAWINGS

The accompanying drawings, which are incorporated herein and constitute part of this specification, illustrate exemplary embodiments of the invention, and together with the general description given above and the detailed description given below, serve to explain the features of the invention.

FIG. 1 illustrates an embodiment junction box mounted onto the base plate of a solar cell module.

FIG. 2 is a perspective view of the junction box of FIG. 1.

FIG. 3 is a perspective top side view of the junction box of FIG. 1.

FIG. 4 is another perspective top side view of the junction box of FIG. 1.

FIG. 5 is a side view of a sealing member of the junction box of FIG. 1.

FIG. 6 is perspective view of the junction box and base plate of FIG. 1 after an inverter is assembled with the junction box.

FIG. 7 is a perspective view of the junction box of FIG. 1 before the inverter and the junction box are assembled together.

FIG. 8 is a circuit block diagram of an embodiment PCB.

### DETAILED DESCRIPTION

The systems, methods, and devices of the various embodiments provide a solar cell module which may ensure a tight connection between a junction box and an external function module. The various embodiments provide a solar cell module having a junction box which may independently support an external function module and may firmly fix the external function module onto a base plate of the solar cell module, thereby simplifying the connecting structures between the external function box, the junction box, and the base plate of the solar cell module. The various embodiments provide a solar cell junction box which may enable a solar cell system to track the maximum power point of the solar cell modules in the solar cell system. In an embodiment, a junction box may include a printed circuit board (“PCB”).

In an embodiment, a solar cell module may ensure a tight connection between a junction box and an external function module. In an embodiment, a solar cell module may have a junction box which may independently support an external function module, may firmly fix the external function module onto a base plate of the solar cell module, and may simplify the connecting structures between the external function box, the junction box and the base plate of the solar cell module. In another embodiment, a solar cell system may include such a solar cell module.

In an embodiment, a solar cell module may include a base plate having a front surface receiving light, a back surface, and a junction box on the back surface. The junction box may include a housing, a pair of retaining arms extending from two sides of the housing, and a receiving area defined between the two retaining arms. In an embodiment, each retaining arm may include engaging structures or fixtures. In another embodiment, a solar cell module may include a base plate having a front surface receiving light, a back surface, and a junction box on the back surface that may include a housing, a pair of retaining arms extending from two sides of the housing, and a receiving area. The junction box may also have a top surface facing the back surface of the base plate and adhesive areas which may be located on the housing and the retaining arms.

In an embodiment, adhesive areas on the junction box may include an area on the top surface of the junction box surrounding an external module. In another embodiment, adhesive areas may include an area on the top surface and an area on the outline of the retaining arms of the junction box. In a further embodiment, the adhesive areas may be included on additional areas of the junction box which may be on the top surface and surrounding an outline of the housing. In a further embodiment, the adhesive areas may include a slot surrounding an outline of the housing and a caved zone which may be defined on an inner side of the slot. In a further embodiment, there may be at least two holes located inside of the additional area and formed on two sides of the slot. In a further embodiment, the retaining arms may include a transverse portion extending from the housing and a pair of longitudinal portions perpendicularly extending from the transverse portion. In the various embodiments, the engaging structures or fixtures of the junction box may include a pair of locking plates longitudinally extending from an inner side edge of the transverse portion. In the various embodiments, the adhesive areas may include a third area including several receiving slots which may be defined on a top surface of the transverse portion of the junction box and which may extend longitudinally.

In a further embodiment, the pair of locking plates on the junction box may include a top plate and a bottom plate which may be vertically arranged, with the bottom plate and the top plate configured to define a groove there between for engaging with a side edge of the external module. The bottom plates of the junction box may extend longer than the top plate along the direction of extension. In a further embodiment, the engaging structures or fixtures of the junction box may include a pair of guiding plates protruding transversely from an inner side edge of the longitudinal portion of the junction box. In a further embodiment, the base plate of the solar panel may include a frame, and the junction box may include lateral edges which may be laid against the frame. In a further embodiment, the adhesive areas of the junction box may further include a fourth area defined between the frame and the lateral edges of the junction box. In a further embodiment, the pair of guiding plates of the junction box may include a bottom guiding plate and a top guiding plate parallel to the bottom guiding plate, the bottom guiding plate and the top guiding plate defining a guiding slot, the bottom guiding plate extending longer than the top guiding plate along an extending direction. In a further embodiment, the junction box may further include several ribs protruding into the fourth adhesive area from the lateral edges.

In a further embodiment, the housing of the junction box and the retaining arms of the junction box may together define a U-shaped receiving area. In an embodiment, the retaining arms of the junction box may have engaging structures or fixtures protruding into the receiving area. In a further embodiment, the retaining arms may include a locking aperture configured to engage with the external module. In an embodiment, the junction box may further include an electrical connector configured to engage with an external function module, and the electrical connector may include a sealing member which may have an E-shaped cross section.

In an embodiment, the junction box may include a housing and a pair of retaining arms extending from two sides of the housing, the retaining arms having engaging structures or fixtures, and an inverter retained on the back surface of the base plate. The base plate may include a middle portion and an edge portion which may be thinner than the middle portion and configured to engage with the engaging structures or fixtures.

In a further embodiment, the retaining arms of the junction box may include a transverse portion extending from two sides of the housing and a pair of longitudinal portions extending perpendicularly from the transverse portion. The inverter may be partially received in a receiving area in the junction box defined by the transverse portion and the longitudinal portions. In a further embodiment, the engaging structures or fixtures of the junction box may include one pair of locking plates extending longitudinally from an inner side edge of the transverse portion, and the edge portion of the inverter may be configured to be sandwiched between the locking plates. In a further embodiment, the engaging structures or fixtures of the retaining arms of the junction box may include one pair of guiding plates extending transversely from an inner side of the longitudinal portions, and the edge portion of the inverter may be configured to be slideable between the pair of guiding plates. In a further embodiment, the retaining arm may have a locking aperture, and the edge portion of the inverter may have a flexible hook configured to engage with the locking aperture.

Compared to a traditional solar cell module, the advantages of the present embodiments may be to define a pair of retaining arms and a receiving area on the junction box, which may engage with an external module and take the heavy load off the external function module. In this manner, the structures between the external function module, junction box, and base plate of the solar cell module may be simplified and the manufacture processes and costs may be reduced. Compared to a traditional solar cell module, the advantages of the present embodiments may be to define a pair of retaining arms and a receiving area for the junction box which may enlarge the areas for engaging with the external function module. Additionally, the housing and the retaining arms of the junction box may define adhesive areas enlarging the contact area between the junction box and the base plate, which may firmly fix the junction box onto the base plate of the solar cell module. In this manner, the junction box may independently support the external function module, and further simplify the connecting structures between the external function module, the junction box, and the base plate of the solar cell module.

In an embodiment, a solar cell junction box may be retained on a solar cell panel and may include an insulated base, a printed circuit board (“PCB”) retained in the insulated base, and a cover covering on the insulated base. In an embodiment, the junction box may further include a temperature sensor and a data storage unit which may be soldered onto the PCB. In a further embodiment, the PCB may include a plurality of electrical terminals mounted thereon which may be connected to the temperature sensor, the data storage unit, and the solar cell panel. In a further embodiment, the electrical terminals may be located on one side edge of the PCB and include a first terminal and a fifth terminal respectively connecting with a positive pole and a negative pole of the solar cell panel, a second terminal and a fourth terminal connecting with the data storage unit and temperature sensor, respectively, and a third terminal both connecting with the temperature sensor and the data storage unit for grounding. In a further embodiment, the insulated base may include a connector retained on one side thereof for electrically connecting with the electrical terminals.

In an embodiment, the insulated base of the junction box may include a housing, a pair of retaining arms perpendicularly extending from two sides of the housing, a receiving area defined between the housing and retaining arms, and engaging structures or fixtures protruding into the receiving area from the retaining arms for engaging with an external function module.

In a further embodiment, the temperature sensor may be retained on one side of the PCB which may be facing the solar cell panel, and the solar cell module may further include heat-conducting adhesive paste connecting the temperature sensor and the solar cell panel so that the temperature sensor may detect the temperature of the solar cell panel directly. In an embodiment, the insulated base may include a housing, a pair of retaining arms perpendicularly extending from two sides of the housing, a receiving area defined between the housing and the retaining arms, and engaging structures or fixtures protruding into the receiving area from the retaining arms for engaging with an external function module.

Compared to a traditional solar cell junction box, an advantage of the various embodiments may be to provide a PCB inside of the junction box including a temperature sensor and a data storage unit. In this manner, the temperature sensor may detect the temperatures of the solar cell modules and transmit the temperature data to an external inverter, and the inverter may receive data of IV curves from the data storage unit. In this manner, the external inverter may track the maximum power point of the solar cell module and realize Hot Spot Suppression (“HSS”), thus bypass diodes may not be necessary, and the power loss caused by bypass diodes may be avoided.

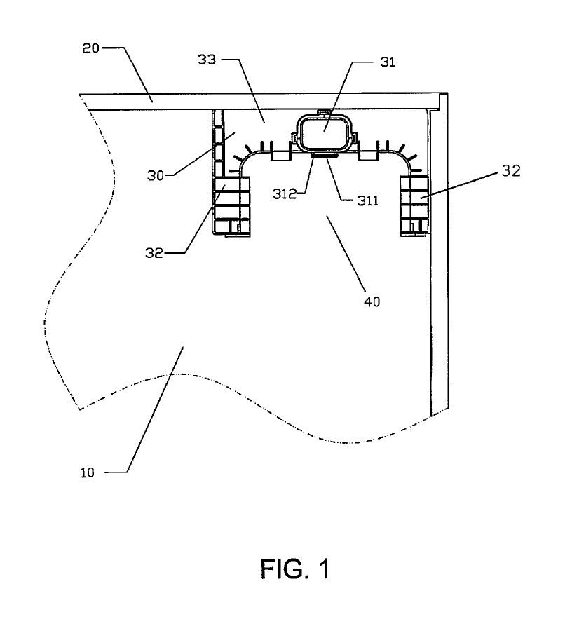

FIG. 1 illustrates a solar cell module according to an embodiment. The solar cell module may include a solar cells base plate 10 and a junction box 30 mounted on a back surface of the base plate 10. A front surface of the base plate 10 may be used to carry a plurality of solar cells which may absorb sunlight and convert the sunlight into electric current. The solar cells may be connected with each other and firmly packaged by a frame 20 to form a solar cell panel including a plurality of arrays of solar cells. The solar cells may absorb the sunlight and then generate two different types of electric charges on two sides of a solar cell which is called the photovoltaic effect. The two sides of the solar cell may then generate two electromotive forces which may convert the light to electric current. A solar cell may be formed from two or more slices of silicon, such as Monocrystalline silicon, Polycrystalline silicon, or Amorphous silicon. A solar cell base plate 10 may define a front surface for light receiving and a back surface on a rear side of the front surface. FIG. 1 illustrates a back surface of the base plate 10. The solar cell base plate 10 may have a frame 20 surrounding four sides of the base plate 10 to firmly package all the solar cells. The junction box 30 may include a housing 31 and a retaining arm 32 extending from the housing 31. The junction box 30 may include a bottom surface 33, and the retaining arm 32 may define a U-shaped receiving area 40. The junction box 30 may include a sealing member 312 and an electrical connector 311.

In an embodiment, the housing 31 may include a connector 311 retained on a longitudinal sidewall to connect with an external function module. The connector 311 may include a mating port on one side surface and a sealing member 312 surrounding a protruding portion of the connector 311. The sealing member 312 may enable the formation of a sealed connection between the external function module and the junction box 30 when connected with each other. In this manner, water may be prevented from penetrating into the housing 31 of junction box 30.

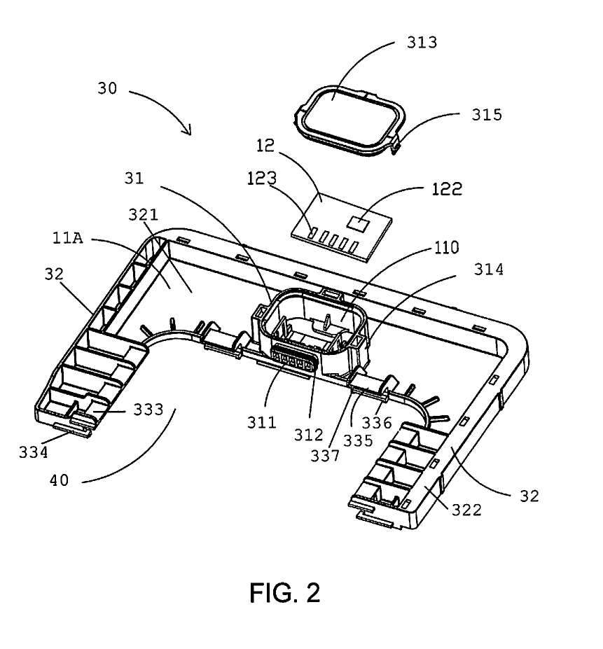

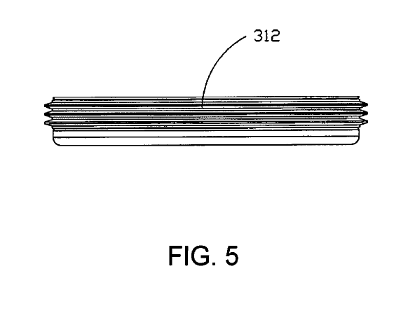

FIGS. 2, 3, and 4 illustrate, the junction box 30 including a housing 31 and a retaining arm 32 extending from the housing 31. The housing 31 may include a box portion 314 and a cover 313 covering the box portion 314. The box portion 314 may have one pair of vertical engaging slots while the cover 313 may have one pair of engaging arms 315 engaging with the engaging slots to form a firm connection between the box portion 314 and the cover 313. The cover 313 may have a seal ring on a bottom side to keep moisture out of the inside space of the box portion 314. An electrical connector 311 may be attached on a sidewall of the box portion 314 for connecting with an external module. The electrical connector 311 may have a mating port on a side surface and a sealing member 312 surrounding a protruding portion of the electrical connector 311. As illustrated in FIG. 5, The sealing member 312 may have an E-shaped cross section by which a sealed connection may be formed between the junction box and the external module, and thus water penetration into the inner side of the housing 31 may be avoided.

The retaining arm 32 may include a transverse portion 321 extending from the housing 31 of the junction box 30 and one pair of longitudinal portions 322 extending from two ends of the transverse portion 321. The longitudinal portion 322 and the transverse portions 321 may define an angle between them. In an embodiment, the angle between the longitudinal portion 322 and the transverse portions 321 may be a right angle. In alternative embodiments, the angle may be an acute angle or an obtuse angle. The junction box 30 may have a bottom surface 33 and a top surface 34. The housing 31 of the junction box 30 and the retaining arm 32 may define a U-shaped receiving area 40. The retaining arm 32 may have engaging structures or fixtures which protrude into the receiving area 40. As illustrated in FIG. 2, the engaging structures or fixtures may include at least one locking plate which may extend from an inner side of the transverse portion 321. In an embodiment, there may be one pair of locking plates. In an alternative embodiment, there may be several pairs of locking plates. In an embodiment, there may be two pairs of locking plates which may be disposed on the sides of the housing 31. Each pair of locking plates may include a top plate 336 and a bottom plate 335 which may be vertically arranged. The bottom plate 335 may extend from a bottom surface 33 of the junction box 30 while the top plate 336 may extend from a top surface 34 of the junction box 30. The bottom plate 335 and the top plate 336 may define a groove 337 for engaging with a side of the external module. The bottom plate 335 may extend much longer than the top plate 336 along an extending direction.

As illustrated in FIG. 2, the engaging structures or fixtures may further include two pairs of guiding plates each of which transversely protrudes from an inner side of each longitudinal portion 322. In an embodiment, the guiding plates can also be formed only on one longitudinal portion 322. Each pair of guiding plates may include a bottom guiding plate 333 and a top guiding plate 334, which may be vertically disposed and define a longitudinal-extended guiding slot. The bottom guiding plate 333 may extend from the bottom surface 33 (illustrated in FIG. 1) of the junction box 30 farther than the top guiding plate 334 extends from the junction box 30.

As illustrated in FIG. 2, in an embodiment the junction box 30 may include a structural insulated base 11A, a PCB 12 retained inside of the structural insulated base 11A, and a cover 313 covering the structural insulated base 11A. In an embodiment, the structural insulated base 11A may include the housing 31 and the pair of retaining arms 32 perpendicularly extending from two sides of the housing 31. The housing 31 may define a receiving area 110 for receiving the PCB 12.

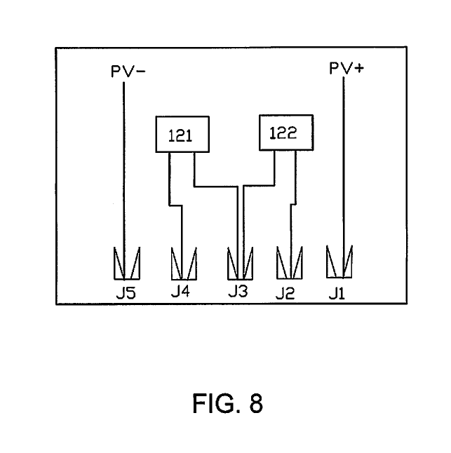

In an embodiment, the junction box 30 may include a temperature sensor 121 and a data storage unit 122 which may both be mounted on the PCB 12 as illustrated in FIG. 8. The data storage unit 122 and temperature sensor 121 may be located on a same side of the PCB or on two different sides of the PCB. As illustrated in FIG. 2, the PCB may further include several electrical terminals 123 which respectively connect with the temperature sensor 121, data storage unit 122, and the positive and the negative poles of the solar cell panel 21. The electrical terminals 123 may be located on one a side edge of the PCB 12 and, as illustrated in FIG. 8 may include a first terminal J1 and a fifth terminal J5 connecting with a positive pole PV+ and a negative pole PV− of the solar cell panel 21, respectively, a second terminal J2 and a fourth terminal J4 connecting with the data storage unit 122 and temperature sensor 121, respectively, and a third terminal J3 connecting with both the temperature sensor 121 and the data storage unit 122 for grounding.

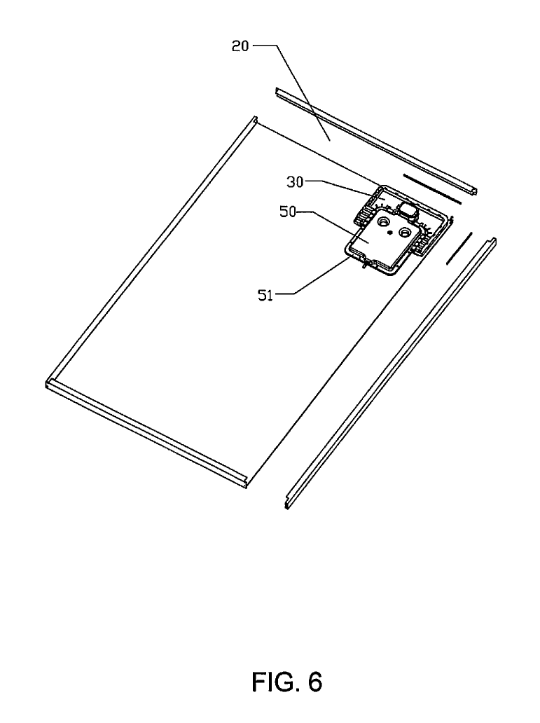

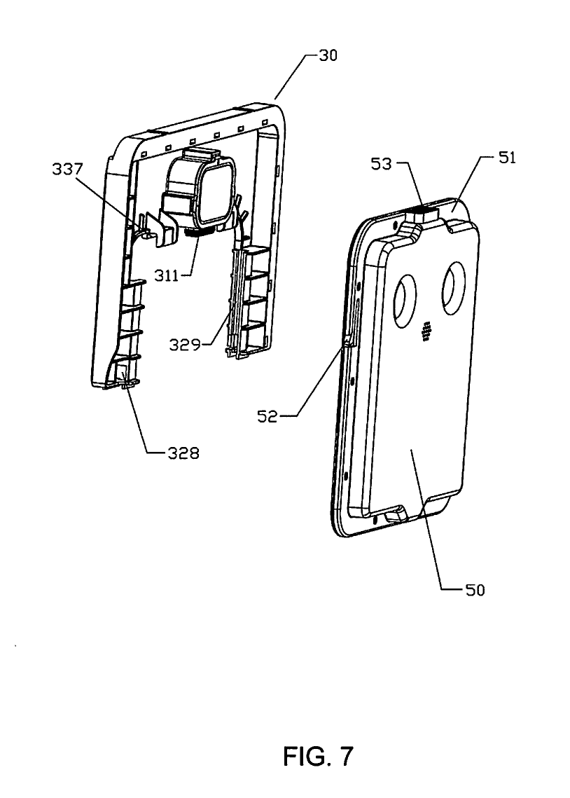

In an embodiment, the external module 50 may be an inverter. FIGS. 6 and 7 illustrate an embodiment of the inverter 50. The inverter 50 may include a middle portion and an edge portion 51 which may be thinner than the middle portion. The middle portion may have a mating electrical connector 53 at one end for engaging with the electrical connector 311 of the junction box 30, while the edge portion 51 may have a flexible hook 52. When the inverter 50 mates with the junction box 30 (as shown in FIG. 6), the guiding plates 333, 334 may guide the inverter 50 to slide into the receiving area 40 of the junction box 30, and the edge portion 51 of the inverter 50 may engage the groove 337 which may be located between the locking plates 335, 336 so that the inverter 50 may firmly connect with the junction box 30. Each longitudinal portion 322 of the retaining arm 32 may include a locking aperture 328, which may be formed on an inner wall between the guiding plates 333, 334, and which may lock with a hook of the inverter 50 to form a firm connection between the locking aperture 328 and the inverter 50. In alternative embodiments, the locking aperture 328 of longitudinal portion 322 and the hook of inverter 50 may be in other positions on the longitudinal portion 322 and the inverter 50.

In an embodiment, the inverter 50 may be placed in the receiving area 40 of the junction box 30, and the transverse portion 321 and longitudinal portion 322 of the retaining arm 32 may support the inverter 50 to strengthen the connection between the inverter 50 and the junction box 30. In a further embodiment, the top surface 34 of the junction box 30 may mate with the back surface of the base plate 10, such that the bottom surface 33 of the junction box 30 may be located under the top surface 34. The dimensions of the bottom plate 335 and bottom guiding plate 333 extending from the bottom surface 33 into the receiving area 40 may be longer than that of the top plate 336 and top guiding plate 334, which may both extend from the top surface 34. As a result, a supporting area of the junction box 30 for supporting the inverter 50 may be increased and the weight-bearing ability of the junction box 30 may also be increased.

FIG. 6 illustrates an embodiment solar cell system in which the junction box 30 is mated with the inverter 50. The inverter 50 may electrically connect with the PCB 12 by a connector 311 (illustrated in FIG. 2). In an embodiment, the temperature sensor 121 may test the temperature of the solar cell panel, and transmit the temperature data to the inverter 50 via the connector 311. In this manner, the inverter 50 may receive real-time monitoring of the temperature of the solar cell. In an embodiment, the data storage unit 122 may send the IV curve data of the solar cell and temperature coefficient tested under STC, to the inverter 50. In an embodiment, the data may be provided as a reference basis for the inverter 50 when the inverter 50 is running, which may help the inverter 50 calculate the real-time IV curves data and rapidly track the maximum power point of the solar cell, thereby enabling “Hot Spot Suppression”.

As mentioned above, in an embodiment, the data storage unit 122 may provide reference basis data such that the inverter 50 may prevent the “Hot Spot Effect” from occurring on the solar cell. In this manner, bypass diodes inside the junction box 30 to protect the solar cell may not be needed, and the power loss of the solar cell caused by bypass diodes may be avoided. In a further embodiment, the temperature sensor 121 may provide real-time temperature data of the solar cell panel such that the inverter 50 may determine a real-time IV curve and monitor the real-time condition of the solar cell panel. In this manner, the solar cell panel may operate safely, and the maximum power point of the solar cell panel may be tracked rapidly.

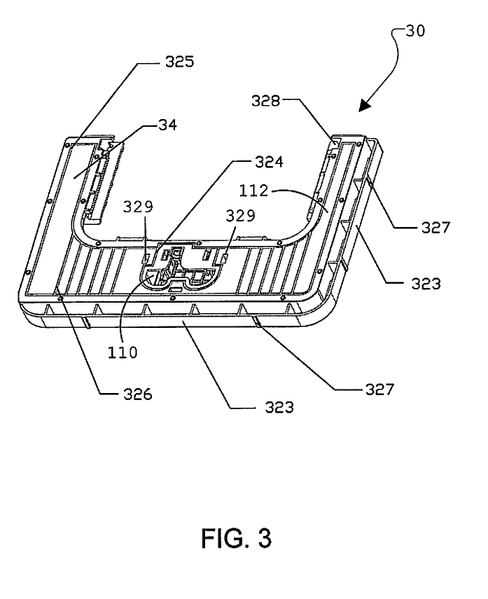

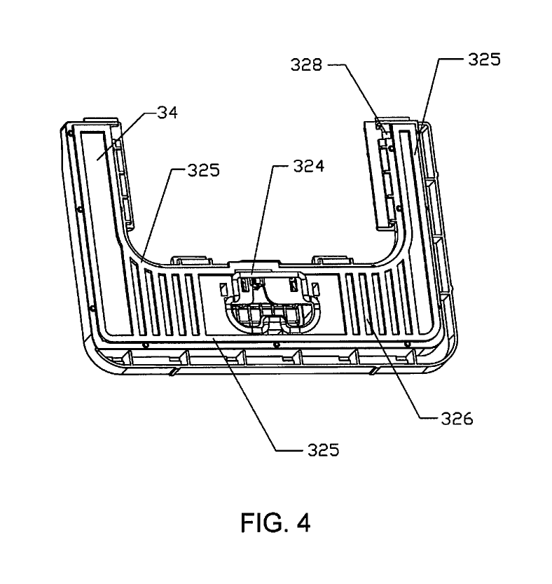

As illustrated in FIGS. 3 and 4 the junction box 30 may include adhesive areas which may be covered by thermally conductive material for firmly assembling the junction box 30 onto the solar cell base plate 10. In an embodiment, the thermally conductive material may act as an adhesive and thermal interface. In an embodiment, the thermally conductive material may be directly or indirectly painted onto the adhesive areas. In an embodiment, the top surface 34 of the junction box 30 may define at least one slot for receiving the thermally conductive material. In an embodiment, the adhesive areas may include a first area defined on the top surface 34 of the retaining arms 32 and a second area defined on the housing 31 of the junction box 30. In an embodiment, the first area may include a first slot 325 which may surround an outline of the retaining arms 32, while the second area may include a second slot 324 which may surround an outline of the housing 31. In an embodiment, the first slot 325 and/or the second slot 324 may be connected and/or unconnected. In an embodiment, the first slot 325 and/or the second slot 324 may be covered by thermally conductive material. In this manner, the junction box 30 may be firmly connected onto the back surface of the base plate 10 with less paste. In an embodiment, the second slot 324 may be formed to surround an opening of the housing 31 of the junction box 30, the thermally conductive material in the second slot 324 may also be used as a seal member for preventing water penetration into the housing 31 of the junction box 30. In another embodiment, there may be two square-shaped through holes 329 on an outside of the second slot 324 which may be formed when the second slot 324 is molded or tooled. In an embodiment, the second slot 324 may have a protrusion on an inner surface for engaging with a leg of the cover 313. In an embodiment, the second adhesive area may further include two caved zones which may be defined on two sides of the second slot 324 for improving the sealing effect. In an embodiment, the adhesive areas may further include a third adhesive area that may have several receiving slots 326 which may be defined on the top surface 34 of the transverse portion 321 and which may extend longitudinally. In an embodiment, the receiving slots 326 may be parallel to each other and connected with the first slot 324 and second slot 325. In this manner, the connection between the junction box 30 and the base plate 10 may be improved.

FIGS. 3 and 4 illustrates the structural insulated base 11A of the junction box 30 having one side surface which may face to the solar cell panel and which may be painted with paste so that the junction box may be firmly retained on the base plate 10. In an embodiment, the temperature sensor 121 may be retained on one side of the PCB which may be facing to the base plate 10 such that the temperature sensor 121 may exactly detect the temperature of solar cell panel. The solar cell module may further include thermally conductive material connecting with the temperature sensor 121 and the solar cell panel for conducting heat. The data storage unit 122 of the PCB 12 may collect data of IV curves and temperature from the solar cell panel under STC.

As illustrated in FIGS. 1 and 6, in an embodiment, the junction box 30 may be mounted onto the base plate 10 of the solar cell module, such that the two adjacent lateral edges 323 of the junction box 30 may be at a right angle to the two sidewalls of the frame 20. In an embodiment, the adhesive areas may further include a fourth area which may be located on the two sidewalls of frame 20 and the two adjacent lateral edges 323 (FIG. 3) of the junction box 30. The lateral edges 323 may include a plurality of ribs 327 protruding into the fourth area. The ribs 327 may increase the adhesive force between the thermally conductive material and the frame 20 and also improve the connection reliability between the junction box 30 and the base plate 10. The junction box 30 may be adhered to the frame 20, and in this manner the frame 20 may also improve the junction box's 30 ability to support the heavy load such that that the junction box 30 may be firmly adhered to the base plate 10 even after the external function module may be added.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

What is claimed is:

1. A solar cell module, comprising:
a base plate having a front surface configured to receive light and a back surface; and
a junction box attached to the back surface, the junction box including:
a housing;
a pair of retaining arms extending from two sides of the housing; and
a receiving area defined between the two retaining arms, wherein each retaining arm includes an engaging structure configured to engage with an external module.

2. The solar cell module of claim 1, wherein:
the junction box includes a pair of locking plates including a top plate and a bottom plate which are vertically arranged;
the bottom plate and the top plate define a groove for engaging with a side edge of the external module; and
the bottom plate extends longer than the top plate in an extending direction.

3. The solar cell module of claim 2, wherein:
the engaging structure includes a pair of guiding plates protruding transversely from an inner side edge of a longitudinal portion;
the pair of guiding plates includes a bottom guiding plate and a top guiding plate parallel to the bottom guiding plate;
the bottom guiding plate and the top guiding plate define a guiding slot; and
the bottom guiding plate extends longer than the top guiding plate in an extending direction.

4. The solar cell module of claim 1, wherein:
the receiving area is U-shaped and the engaging structure protrudes into the receiving area from the retaining arms; and
the retaining arms include a locking aperture configured to engage with the external module.

5. The solar cell module of claim 1, wherein the external module is an inverter, the solar cell module further comprising the inverter coupled to the back surface of the base plate, the inverter comprising:
a middle portion; and
an edge portion which is thinner than the middle portion and configured to engage with the engaging structure.

6. The solar cell module of claim 5, wherein the retaining arms include a transverse portion extending from two sides of the housing and a pair of longitudinal portions extending perpendicularly from the transverse portion, and
wherein the inverter is partially located in a receiving area defined by the transverse portion and the longitudinal portions.

7. The solar cell module of claim 6, wherein the engaging structure includes one pair of locking plates extending longitudinally from an inner side edge of the transverse portion, and
wherein the edge portion of the inverter is configured to be sandwiched between the locking plates.

8. The solar cell module of claim 5, wherein the engaging structure of the retaining arms includes one pair of guiding plates extending transversely from an inner side of the longitudinal portions, and
wherein the edge portion of the inverter is configured to be slide-able between the pair of guiding plates.

9. The solar cell module of claim 5, wherein the retaining arm includes a locking aperture, and
wherein the edge portion of the inverter includes a flexible hook configured to engage with the locking aperture.

10. The solar cell module of claim 1, wherein the junction box includes a top surface facing the back surface of the base plate, and
wherein the junction box includes adhesive areas which are located on the housing and the retaining arms.

11. The solar cell module of claim 10, wherein the adhesive areas include a first area which is defined on the top surface and surrounds an outline of the retaining arms.

12. The solar cell module of claim 11, wherein the adhesive areas further include a second area which is defined on the top surface and surrounds an outline of the housing.

13. The solar cell module of claim 12, wherein the second area includes a slot surrounding an outline of the housing, a caved zone which is defined on an inner side of the slot, and at least two through holes formed on two sides of the slot.

14. The solar cell module of claim 13, wherein the retaining arms include a transverse portion extending from the housing and a pair of longitudinal portions extending perpendicularly from the transverse portion.

15. The solar cell module of claim 14, wherein the adhesive areas further include a third area, the third area including receiving slots on a top surface of the transverse portion and extending longitudinally.

16. The solar cell module of claim 15, wherein the base plate includes a frame and the junction box includes lateral edges which are laid against the frame, and
wherein the adhesive areas further include a fourth area defined between the frame and the lateral edges.

17. The solar cell module of claim 16, wherein the junction box includes ribs protruding into the fourth area from the lateral edges.

18. The solar cell module of claim 10, wherein the junction box further includes an electrical connector configured to engage with the external module, and wherein the electrical connector includes a sealing member which has an E-shaped cross section.

19. The solar cell module of claim 1, wherein the base plate is a solar cell panel, and wherein the junction box further comprises:
an insulated base;
a printed circuit board (“PCB”) retained in the insulated base, the PCB including a temperature sensor and a data storage unit soldered on the PCB, and a plurality of electrical terminals connected with the temperature sensor, the data storage unit, and the solar cell panel; and
a cover covering the insulated base.

20. The solar cell module of claim 19, wherein:
the electrical terminals are located on one side edge of the PCB and include a first terminal and a fifth terminal respectively connected with a positive pole and a negative pole of the solar cell panel, a second terminal and a fourth terminal respectively connected with the data storage unit and the temperature sensor, and a third terminal both connected with the temperature sensor and the data storage unit; and
the insulated base includes a connector on one side for electrically connecting with the electrical terminals.

21. The solar cell module of claim 20, wherein:
the external module is an inverter;
the inverter is attached on the back surface of the solar cell panel and electrically connected with the PCB inside of the junction box;
the inverter is configured to collect data from the temperature sensor and the storage unit;
the temperature sensor is attached on a surface of the PCB which is facing the solar panel; and
the solar cell module includes thermally conductive material connecting the temperature sensor and the solar cell panel such that the temperature sensor can detect the temperature of the solar cell panel.

22. A solar cell module junction box, comprising:
a housing;
a pair of retaining arms extending from two sides of the housing;
a U-shaped receiving area defined between the two retaining arms, wherein each retaining arm includes an engaging structure protruding into the U-shaped receiving area and configured to engage with an external module;
a pair of locking plates, including a top plate and a bottom plate which are vertically arranged, wherein the bottom plate and the top plate define a groove for engaging with a side edge of the external module and the bottom plate extends longer than the top plate in an extending direction;
a top surface;
a first adhesive area which is defined on the top surface and surrounds an outline of the retaining arms;
a second adhesive area which is defined on the top surface and surrounds an outline of the housing, wherein the second area includes a slot surrounding an outline of the housing, a caved zone which is defined on an inner side of the slot, and at least two through holes formed on two sides of the slot;
a third adhesive area including receiving slots on a top surface of the transverse portion and extending longitudinally;
an insulated base;
a printed circuit board (“PCB”) retained in the insulated base, the PCB including a temperature sensor and a data storage unit soldered on the PCB, and a plurality of electrical terminals connected with the temperature sensor and the data storage unit, wherein the electrical terminals are located on one side edge of the PCB and include a first terminal and a fifth terminal, a second terminal and a fourth terminal respectively connected with the data storage unit and the temperature sensor, and a third terminal both connected with the temperature sensor and the data storage unit; and
a cover covering the insulated base.
